(19) United States
(12) Patent Application Publication
(10) Pub. No.: US 2014/0067293 A1
(43) Pub. Date: Mar. 6, 2014

(54) POWER SUB-STATE MONITORING

(71) Applicant: APPLE INC., Cupertino, CA (US)

(72) Inventors: Nima Parivar, South San Francisco, CA (US); Christopher T. Mullens, San Francisco, CA (US); Kelsey Y. Ho, Los Altos, CA (US)

(73) Assignee: APPLE INC., Cupertino, CA (US)

(21) Appl. No.: 13/627,249

(22) Filed: Sep. 26, 2012

Related U.S. Application Data
(60) Provisional application No. 61/697,172, filed on Sep. 5, 2012.

(51) Int. Cl. G01R 21/00; G06F 19/00

(52) U.S. Cl. 702/60

(57) ABSTRACT

An electronic device that includes an integrated circuit and a memory is described. This integrated circuit monitors power sub-states within different operating modes of the electronic device. These power sub-states are associated with configurations of the electronic device and average power-consumption rates. Then, the integrated circuit stores information specifying a power-sub-state history of the electronic device in the memory, where the power-sub-state history includes amounts of time the electronic device was in one or more of the power sub-states. The stored information can be used to improve a power usage model for the electronic device and/or to modify a user experience, such as changing a performance of the electronic device or a time until a battery needs to be recharged.

### CROSS REFERENCE TO RELATED APPLICATIONS

This application claims priority under 35 U.S.C. §119(e) to U.S. Provisional Application Ser. No. 61/697,172, entitled “Power Sub-State Monitoring,” by Nima Parivar, Christopher T. Mullens and Kelsey Y. Ho, Attorney docket number APL-P16519USP1, filed on Sep. 5, 2012, the contents of which is herein incorporated by reference.

This application is also related to: U.S. patent application Ser. No. ______, entitled “Tracking Power States of a Peripheral Device,” by Jesse M. Devine and Andrew D. Putman, Attorney Docket No. APL-P16580USP1, filed Sep. ______, 2012, the contents of which are herein incorporated by reference.

### BACKGROUND

1. Field

The described embodiments relate to techniques for monitoring a power-sub-state history of an electronic device.

2. Related Art

A power-usage model is often used while designing electronic devices (such as mice, trackpads, touchscreens, etc.). For example, a power-usage model can be used to provide information about how the electronic device will be used, so that an accurate power budget or battery-life estimate can be calculated. As a consequence, a power-usage model (and the related power budget) directly impacts the design of an electronic device, including the battery size, as well as the size and the shape of the product.

In addition, a power-usage model may be incorporated into a battery model in order to predict remaining battery life. This prediction may be presented to a user of the electronic device, for example, in the form of a remaining time/percentage display or low/critical battery-level notifications.

However, constructing an accurate power-usage model for sophisticated electronic devices can be difficult because users are typically free to use these electronic devices in arbitrary and unexpected ways. Therefore, power-usage models are often constructed by making educated guesses, looking at historical data, or observing users as they interact with electronic devices. These approaches are often inaccurate, which can require more conservative designs (such as electronic devices with larger, heavier batteries) and can make it more difficult to predict the remaining battery life.

### SUMMARY

The described embodiments include an electronic device that includes an integrated circuit and a memory. This integrated circuit monitors power sub-states within different operating modes of the electronic device, where the power sub-states are associated with configurations of the electronic device and average power-consumption rates. Then, the integrated circuit stores information specifying a power-sub-state history of the electronic device in the memory, where the power-sub-state history includes amounts of time the electronic device was in one or more of the power sub-states.

Note that a given configuration includes hardware and software configurations. Furthermore, at least some of the configurations include different values of: a sampling rate, a backlight intensity, a display refresh rate, a transmit power, a processor state, a speaker volume, and/or a communication mode.

In some embodiments, the electronic device includes an interface circuit that communicates information with another electronic device, and the integrated circuit transmits the power-sub-state history to the other electronic device using the interface circuit. For example, the integrated circuit may transmit the power-sub-state history periodically. Alternatively, the integrated circuit may transmit the power-sub-state history after a request is received via the interface circuit.

Furthermore, in some embodiments the electronic device converts the monitored power sub-states into power-consumption values based on the average power-consumption rates associated with the power sub-states, and the stored information includes the power-consumption values.

Additionally, in some embodiments the electronic device modifies a user experience associated with the electronic device based on the stored information. For example, the electronic device may include a power source, and modifying the user experience may affect an operating time before the power source is recharged. Alternatively or additionally, modifying the user experience may involve changing a performance of the electronic device.

Another embodiment provides an electronic device that includes a processor with an execution unit or mechanism that performs at least some of the operations of the integrated circuit.

Another embodiment provides the processor.

Another embodiment provides a method for storing information specifying the power-sub-state history of the electronic device. During operation, the electronic device monitors power sub-states within different operating modes of the electronic device, where the power sub-states are associated with configurations of the electronic device and average power-consumption rates. Then, the electronic device stores the information specifying the power-sub-state history of the electronic device in a memory in the electronic device, where the power-sub-state history includes amounts of time the electronic device was in one or more of the power sub-states.

### BRIEF DESCRIPTION OF THE FIGURES

FIG. 1 presents a block diagram illustrating an electronic device in accordance with an embodiment of the present disclosure.

FIG. 2 presents a block diagram illustrating an electronic device in accordance with an embodiment of the present disclosure.

FIG. 3 presents a drawing illustrating power sub-states of the electronic device of FIG. 1 or 2 in accordance with an embodiment of the present disclosure.

FIG. 4 presents a block diagram illustrating a data structure that includes a power-sub-state history of the electronic device of FIG. 1 or 2 in accordance with an embodiment of the present disclosure.

FIG. 5 presents a block diagram illustrating a system that includes the electronic device of FIG. 1 or 2 in accordance with an embodiment of the present disclosure.

FIG. 6 presents a flowchart illustrating a method for storing information specifying a power-sub-state history of the electronic device of FIG. 1 or 2 in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

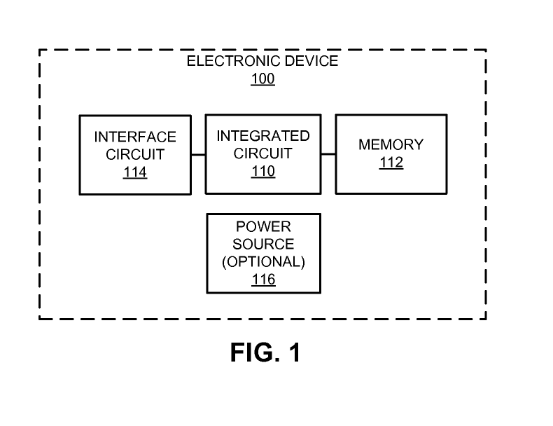

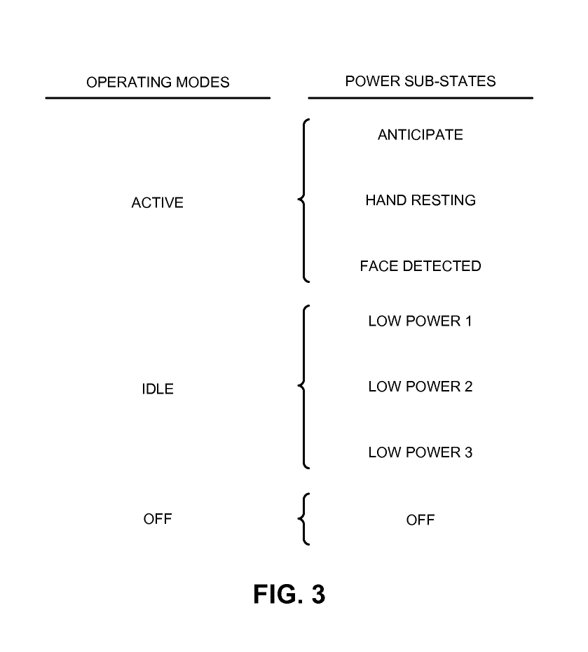

FIG. 1 presents a block diagram illustrating an electronic device 100. This electronic device includes an integrated circuit 110 and a memory 112. Integrated circuit 110 monitors power sub-states within different operating modes of electronic device 100, where the power sub-states are associated with configurations of electronic device 100 and average power-consumption rates. For example, as described below with reference to FIG. 3, even when electronic device 100 is in an ‘active’ operating mode, there may be different power sub-states. Typically, information about these power sub-states is not explicitly provided to external devices. However, by using integrated circuit 110 to monitor the power sub-states, the power-sub-state history (and, thus, the power consumption) of electronic device 100 may be accurately determined. Note that a given configuration of electronic device 100 may include hardware and/or software configurations. Furthermore, at least some of the configurations include different values of: a sampling rate, a duty cycle, a backlight intensity, a display refresh rate, a transmit power, a processor state, a speaker volume, and/or a communication mode (such as a high-power discovery mode).

Then, integrated circuit 110 stores information specifying the power-sub-state history of electronic device 100 in memory 112, where the power-sub-state history includes amounts of time electronic device 100 was in one or more of the power sub-states. In some embodiments, electronic device 100 converts the monitored power sub-states into power-consumption values based on the average power-consumption rates associated with the power sub-states, and the stored information includes the power-consumption values.

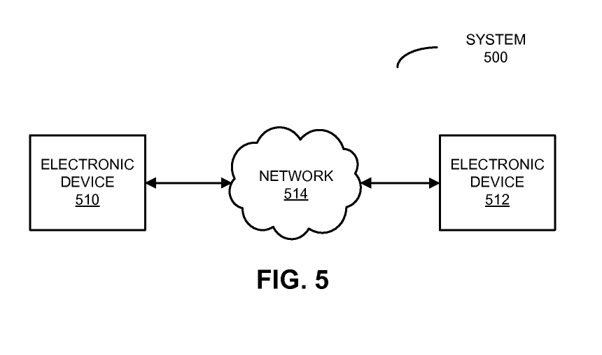

As described further below with reference to FIG. 5, subsequently electronic device 100 may communicate the power-sub-state history to another electronic device. In particular, electronic device 100 may include an interface circuit 114 that communicates information with the other electronic device, and integrated circuit 110 may transmit the power-sub-state history to the other electronic device using interface circuit 114. For example, integrated circuit 110 may transmit the power-sub-state history periodically (such as every 1, 5 or 10 minutes). Alternatively, integrated circuit 110 may transmit the power-sub-state history after a request is received via interface circuit 114, such as a request received from the other electronic device.

As noted previously, in general information about the power sub-states is often hidden or unavailable to external devices (such as a host that interacts with electronic device 100), so by collecting and providing the power-sub-state history electronic device 100 may significantly improve the accuracy of a power-usage model for electronic device 100. In addition to facilitating improved and more accurate designs of other electronic devices, the power-sub-state history may be used to improve battery-life estimates. More generally, electronic device 100 may modify a user experience associated with electronic device 100 based on the stored information. For example, electronic device 100 may include an optional power source 116 (such as a battery), and modifying the user experience may affect an operating time until optional power source 116 is recharged. In particular, electronic device 100 may disable unused or un-necessary sub-modules or sub-states within an operating mode. Alternatively or additionally, modifying the user experience may involve changing a performance of electronic device 100, such as a clock speed or a backlight intensity. Thus, electronic device 100 may reduce the performance to increase the operating time until optional power source 116 is recharged. Furthermore, these modifications may be based on a user input or instruction. For example, the user may be provided several user-experience options on a display (such as a touchscreen), such as high performance, short battery life versus reduced performance, longer battery life, and the user may select the user experience that they prefer.

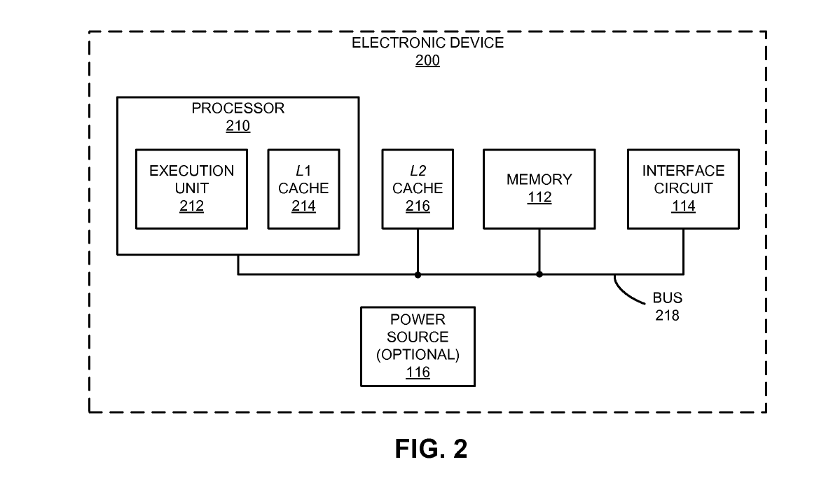

While FIG. 1 illustrates the use of integrated circuit 110 to perform operations in the power-sub-state monitoring technique, in other embodiments at least some of these operations are performed by an embedded system processor, for example, using firmware that includes program code and data for the operations in the power-sub-state monitoring technique. This is illustrated in FIG. 2, which presents a block diagram illustrating an electronic device 200, which includes processor 210 with an execution unit 212 (and, more generally, an execution mechanism) that performs at least some of the operations of integrated circuit 110 (FIG. 1), such as logical operations or computational operations. Furthermore, processor 210 may include L1 cache 214, and electronic device 200 may include L2 cache 216 and memory 112. Components in electronic device 200 may be coupled by a bus 218 or another suitable communication channel (such as signal lines or links).

In some embodiments, L1 cache 214, L2 cache 216 and memory 112 are non-volatile computer-readable storage devices that collectively form a memory hierarchy that stores data and instructions for processor 210. These components may include semiconductor devices with short access times that store copies of frequently used program code or data, such as: dynamic random access memory (DRAM), static random access memory (SRAM), read only memory (ROM), or flash memory. Note that processor 210 can be a general-purpose processor that performs computational operations, and may include one or more processing cores. For example, processor 210 can be: a central processing unit or CPU (such as a microprocessor), a controller, an application-specific integrated circuit (ASIC), or a field-programmable gate array (FPGA).

In an exemplary embodiment, firmware code is used to allow an electronic device to keep track of, and to report, how much time it has spent in each of its power sub-states. This is illustrated in FIG. 3, which presents a drawing illustrating power sub-states of electronic device 100 (FIG. 1) or 200 (FIG. 2). In particular, a touchscreen may have different operating modes with tiers of performance and different amounts of power consumption. For example, an ‘active’ operating mode may include: an ‘anticipate’ power sub-state in which a user is interacting with the touchscreen but only a limited amount of data is communicated to a host; a ‘hand resting’ power sub-state in which no data is communicated to the host; and a ‘face detected’ power sub-state in which no data is communicated to the host. Similarly, an ‘idle’ operating mode may include multiple low-power sub-states that the touchscreen transitions through after time intervals without activity have elapsed. Thus, the touchscreen may be in a first low-power sub-state for 2 s, then in a second low-power sub-state for 10 s, and a third low-power sub-state for 1 minute. Typically, software on the host that is communicating with the touchscreen may only receive information about the active operating mode, the idle operating mode and when the touchscreen is ‘off’ (and, thus, may not receive information about any of the power sub-states). Therefore, without the power-monitoring technique, it would not be possible to accurately determine how long the touchscreen was in each of these power sub-states based solely on the data communicated to the host.

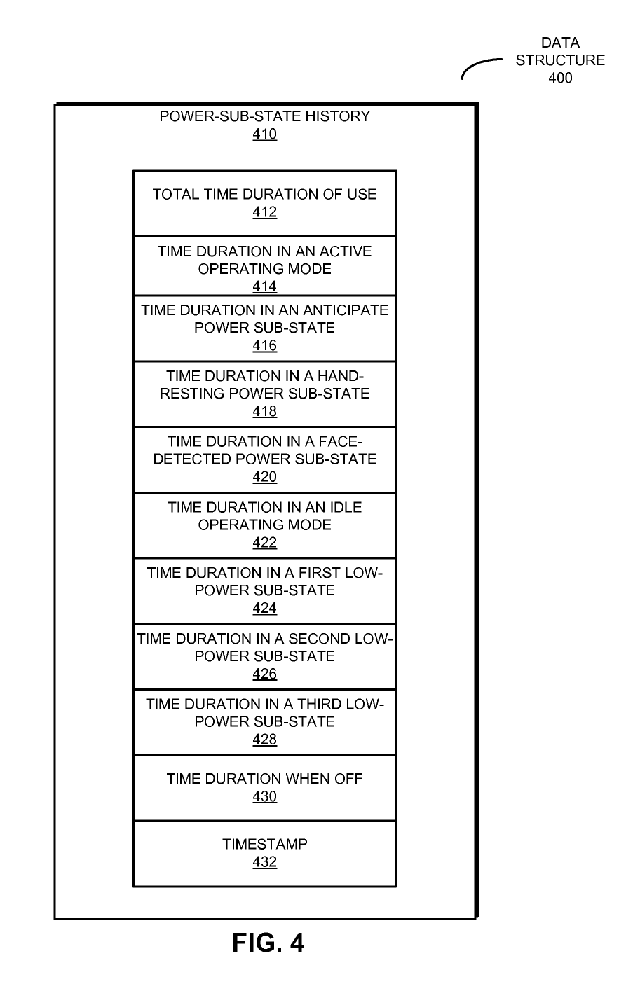

FIG. 4 presents a block diagram illustrating a data structure 400 that includes a power-sub-state history 410 of electronic device 100 (FIG. 1) or 200 (FIG. 2), which may be stored (at least temporarily) in memory 112 (FIGS. 1 and 2). For example, power-sub-state history 410 may be associated with the touchscreen, and may include: a total time duration of use 412, a time duration in an active operating mode 414, a time duration in an anticipate power sub-state 416, a time duration in a hand-resting power sub-state 418, a time duration in a face-detected sub-state 420, a time duration in an idle operating mode 422, a time duration in a first low-power sub-state 424 in the idle operating mode, a time duration in a second low-power sub-state 426 in the idle operating mode, a time duration in a third low-power sub-state 428 in an idle operating mode, a time duration when off 430, and a timestamp 432. Note that entries in power-sub-state history 410 may include power-sub-state information that is queryable (by an external electronic device or host) via interface circuit 114 (FIG. 1) and/or that is logged into a registry associated with optional power source 116.

While FIG. 4 illustrates power-sub-state history 410 with time durations in various operating modes and power sub-states, in other embodiments the power-sub-state history includes a breakdown of the time spent in these various operating modes and power sub-states. For example, the electronic device was in power sub-state A for 600 s all at once. Alternatively, the electronic device was in power sub-state A hundreds of times, for just a couple of seconds each. Because the electronic device may transition between power sub-states after certain timeouts are exceeded, by tracking the number of times the electronic device is in different power sub-states, as well as the time spent in these power sub-states, the power-sub-state history can be used to determine the timeouts and transition rules.

Power-sub-state history 410 may be used in a variety of ways. For example, it may be used to aid in debugging battery-life issues with prototype electronic devices and/or customer's electronic devices. Moreover, by surveying the touchscreens in multiple electronic devices, typical power usage can be determined, which may improve the accuracy of power-usage models and guide improved future product design. Furthermore, the time duration in the different power sub-states may be used to predict the power impact of the touchscreen. For example, a predictive power-management technique may analyze this information in real-time so that more accurate estimates of battery-life consumed (and thus, battery-life remaining) can be presented to a user of an electronic device that includes the touchscreen (i.e., the host). This may also allow the user experience to be modified accordingly, thereby trading off performance with remaining battery power. In addition, the information in power-sub-state history 410 may be analyzed to detect unusual operating conditions, and to take appropriate action (e.g., reset firmware, log a bug, log an error message, etc.). For example, a touchscreen that is consuming more power than expected can be detected (based on the known power consumption in different power sub-states, which may be determined by a manufacturer of the touchscreens) and remedial action may be taken.

One or more of the preceding embodiments of the electronic device may be included in a system. This is shown in FIG. 5, which presents a block diagram illustrating a system 500 that includes electronic device 510 (such as a host) and electronic device 512, such as electronic device 100 (FIG. 1) or 200 (FIG. 2). In this system, firmware executing on electronic device 510 (for example, in a micro-controller) may accumulate data on how much time electronic device 510 spends in each power sub-state. This power-sub-state history can be reported periodically to electronic device 512 or can be reported to electronic device 512 when software (such as a driver) executing in an environment of electronic device 512 interrogates electronic device 510 or requests this information. (For example, the power-sub-state history may be communicated via network 514, which may include a signal line, a wireless connection, an optical connection, a cellular-telephone network and/or the Internet.) Thus, the power sub-state information may be maintained in data structures in memories on electronic devices 510 and 512. The data structure on electronic device 510 may be temporary and the data structure of electronic device 512 may be an aggregate of the power-sub-state history, both over time and from multiple electronic devices (such as electronic device 510). Thus, the software on electronic device 512 may merge one or more instances of the power-sub-state history from one or more electronic devices, such as electronic device 510. In some embodiments, the aggregated information in the data structure on electronic device 512 includes power-consumption information.

Note that the software on electronic device 512 may make the aggregated power-sub-state history and/or the power-consumption information available to other applications executing on electronic device 512, such as a power-management module. For example, based on a command or query, the software may provide the aggregated power-sub-state history and/or the power-consumption information to the one or more applications.

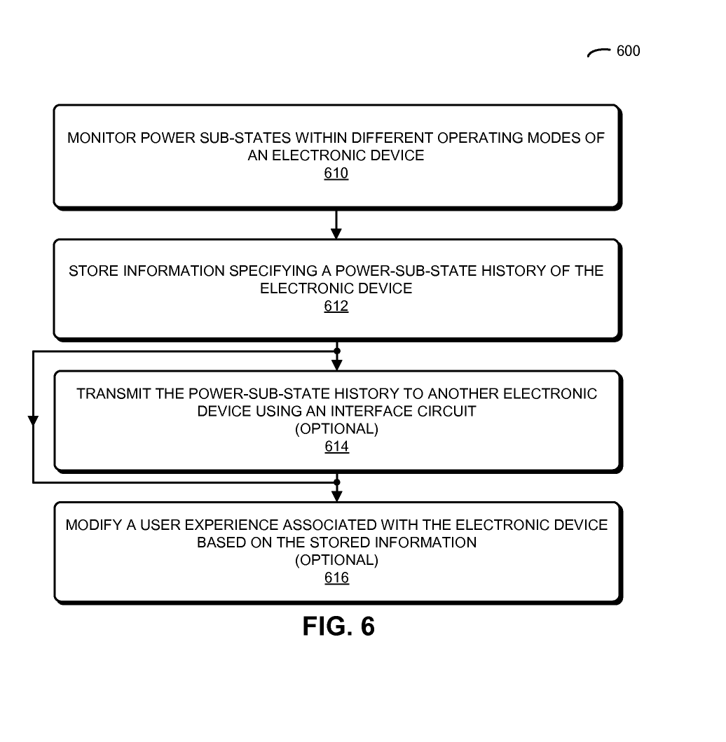

We now describe embodiments of a method. FIG. 6 presents a flowchart illustrating a method 600 for storing information specifying a power-sub-state history of an electronic device, such as electronic device 100 (FIG. 1) or 200 (FIG. 2). During operation, the electronic device monitors power sub-states within different operating modes of the electronic device (operation 610), where the power sub-states are associated with configurations of the electronic device and average power-consumption rates. Then, the electronic device stores the information specifying the power-sub-state history of the electronic device (operation 612) in the memory in the electronic device, where the power-sub-state history includes amounts of time the electronic device was in one or more of the power sub-states.

In some embodiments, the electronic device optionally transmits the power-sub-state history to another electronic device using an interface circuit (operation 614). Furthermore, in some embodiments the electronic device optionally modifies a user experience associated with the electronic device based on the stored information (operation 616).

In some embodiments of method 600, there may be additional or fewer operations. Moreover, the order of the operations may be changed, and/or two or more operations may be combined into a single operation.

Referring back to FIG. 1, in general functions of the electronic device may be implemented in hardware and/or in software. While electrical communication among components in electronic devices 100 and 200 (FIG. 2) has been used as an illustrative example, in general these connections may include electrical, optical, or electro-optical communication of signals and/or data. Furthermore, in the preceding embodiments, some components are shown directly connected to one another, while others are shown connected via intermediate components. In each instance the method of interconnection, or ‘coupling,’ establishes some desired communication between two or more circuit nodes, or terminals. Such coupling may often be accomplished using a number of circuit configurations, as will be understood by those of skill in the art; for example, AC coupling and/or DC coupling may be used.

In some embodiments, functionality in these circuits, components and devices may be implemented in one or more: application-specific integrated circuits (ASICs), field-programmable gate arrays (FPGAs), and/or one or more digital signal processors (DSPs). Moreover, the circuits and components may be implemented using any combination of analog and/or digital circuitry, including: bipolar, PMOS and/or NMOS gates or transistors. Furthermore, signals in these embodiments may include digital signals that have approximately discrete values and/or analog signals that have continuous values. Additionally, components and circuits may be single-ended or differential.

An output of a process for designing an integrated circuit, or a portion of an integrated circuit, comprising one or more of the circuits described herein may be a computer-readable medium such as, for example, a magnetic tape or an optical or magnetic disk. The computer-readable medium may also be encoded with data structures or other information describing circuitry that may be physically instantiated as an integrated circuit or portion of an integrated circuit. Although various formats may be used for such encoding, these data structures are commonly written in: Caltech Intermediate Format (CIF), CalmaGDS II Stream Format (GDSII) or Electronic Design Interchange Format (EDIF). Those of skill in the art of integrated circuit design can develop such data structures from schematics of the type detailed above and the corresponding descriptions and encode the data structures on a computer-readable medium. Those of skill in the art of integrated circuit fabrication can use such encoded data to fabricate integrated circuits comprising one or more of the circuits described herein.

Electronic devices 100 and 200 (FIG. 2) may include one of a variety of devices, including: a desktop computer, a server, a laptop computer, a media player (such as an MP3 player), an appliance, a peripheral device (such as a trackpad, a touchscreen, a mouse, a camera, a display, a keyboard, a user-interface device, etc.), a subnotebook/netbook, a tablet computer, a smartphone, a cellular telephone, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, and/or another electronic device.

One or more of the components may not be present in FIGS. 1-5. In some embodiments, at least one of electronic devices 100 and 200 (FIG. 2) or system 500 (FIG. 5) include one or more additional components that are not shown in FIGS. 1-5. Also, although separate components are shown in FIGS. 1-5, in some embodiments some or all of a given component can be integrated into one or more of the other components and/or positions of components can be changed.

Moreover, although the embodiment shown in FIG. 2 is limited to a particular set of functional blocks, in the described embodiments processor 210 (FIG. 2) can include other functional blocks, such as an instruction fetch unit, an instruction decode unit, a branch unit, a memory management unit, I/O interfaces, etc. coupled to execution unit 212 (FIG. 2). The additional functional blocks that can be present in processor 210 (FIG. 2) are well-known in the art and are not described in more detail.

In some embodiments, system 500 (FIG. 5) is a distributed system, so that electronic devices 510 and 512 (FIG. 5) are at remote locations from each other. For example, system 500 (FIG. 5) may represent a cellular-telephone system.

In the preceding description, we refer to ‘some embodiments.’ Note that ‘some embodiments’ describes a subset of all of the possible embodiments, but does not always specify the same subset of embodiments.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. An electronic device, comprising:
a memory; and
an integrated circuit electrically coupled to the interface circuit and the memory, wherein the integrated circuit is configured to:
monitor power sub-states within different operating modes of the electronic device, wherein the power sub-states are associated with configurations of the electronic device and average power-consumption rates; and
store information specifying a power-sub-state history of the electronic device in the memory, wherein the power-sub-state history includes amounts of time the electronic device was in one or more of the power sub-states.

2. The electronic device of claim 1, wherein a given configuration includes hardware and software configurations.

3. The electronic device of claim 1, wherein at least some of the configurations include different values of a parameter selected from the group consisting of: a sampling rate, a backlight intensity, a display refresh rate, a transmit power, a processor state, a speaker volume, and a communication mode.

4. The electronic device of claim 1, wherein the electronic device further includes an interface circuit, coupled to the integrated circuit, configured to communicate information with another electronic device; and
wherein the integrated circuit is further configured to transmit the power-sub-state history to the other electronic device using the interface circuit.

5. The electronic device of claim 4, wherein the integrated circuit is configured to transmit the power-sub-state history periodically.

6. The electronic device of claim 4, wherein the integrated circuit is configured to transmit the power-sub-state history after a request is received via the interface circuit.

7. The electronic device of claim 1, wherein the electronic device is further configured to convert the monitored power sub-states into power-consumption values based on the average power-consumption rates associated with the power sub-states; and
wherein the stored information includes the power-consumption values.

8. The electronic device of claim 1, wherein the electronic device is further configured to modify a user experience associated with the electronic device based on the stored information.

9. The electronic device of claim 8, wherein the electronic device further includes a power source; and
wherein modifying the user experience affects an operating time before the power source is recharged.

10. The electronic device of claim 8, wherein modifying the user experience involves changing a performance of the electronic device.

11. An electronic device for storing information specifying a power-sub-state history of the electronic device, comprising:
a processor coupled to a memory that stores program code and data for the processor; and
at least one execution unit in the processor configured to:
monitor power sub-states within different operating modes of the electronic device, wherein the power sub-states are associated with configurations of the electronic device and average power-consumption rates; and
store the information specifying the power-sub-state history of the electronic device in the memory, wherein the power-sub-state history includes amounts of time the electronic device was in one or more of the power sub-states.

12. The electronic device of claim 11, wherein the electronic device further includes an interface circuit, coupled to the processor, configured to communicate information with another electronic device; and
wherein at least the one execution unit is further configured to transmit the power-sub-state history to the other electronic device using the interface circuit.

13. The electronic device of claim 11, wherein at least the one execution unit is further configured to convert the monitored power sub-states into power-consumption values based on the power-consumption rates associated with the power sub-states; and
wherein the stored information includes the power-consumption values.

14. The electronic device of claim 11, wherein at least the one execution unit is further configured to modify a user experience associated with the electronic device based on the stored information.

15. A processor for storing information specifying a power-sub-state history of an electronic device, comprising an execution mechanism configured to:
monitor power sub-states within different operating modes of the electronic device, wherein the power sub-states are associated with configurations of the electronic device and average power-consumption rates; and
store the information specifying the power-sub-state history of the electronic device in the memory, wherein the power-sub-state history includes amounts of time the electronic device was in one or more of the power sub-states.

16. The processor of claim 15, wherein the execution mechanism is further configured to transmit the power-sub-state history to another electronic device using an interface circuit.

17. The processor of claim 15, wherein the execution mechanism is further configured to modify a user experience associated with the electronic device based on the stored information.

18. An electronic-device-implemented method for storing information specifying a power-sub-state history of the electronic device, the method comprising:
using the electronic device, monitoring power sub-states within different operating modes of the electronic device, wherein the power sub-states are associated with configurations of the electronic device and average power-consumption rates; and
storing the information specifying the power-sub-state history of the electronic device in a memory in the electronic device, wherein the power-sub-state history includes amounts of time the electronic device was in one or more of the power sub-states.

19. The method of claim 18, wherein the method further comprises transmitting the power-sub-state history to another electronic device using an interface circuit.

20. The method of claim 18, wherein the method further comprises modifying a user experience associated with the electronic device based on the stored information.
